(19) United States
(12) Patent Application Publication
(10) Pub. No.: US 2024/0332319 A1
(43) Pub. Date: Oct. 3, 2024

(54) Electronic Devices with Displays and Conductive Traces

(71) Applicant: Apple Inc., Cupertino, CA (US)

(72) Inventors: Gihoon Choo, San Jose, CA (US); Abbas Jamshidi Roudbari, Saratoga, CA (US); Guanxiong Liu, Campbell, CA (US); Jae Won Choi, San Jose, CA (US); Kyounghwan Kim, San Jose, CA (US); Shyuan Yang, San Jose, CA (US); Sungki Lee, Sunnyvale, CA (US); Ting-Kuo Chang, San Jose, CA (US); Tsung-Ting Tsai, San Jose, CA (US); Wan-Ching Hsu, San Jose, CA (US); Warren S Rieutort-Louis, Cupertino, CA (US); Yishan Liu, Round Rock, TX (US); Zhe Hua, San Jose, CA (US)

(21) Appl. No.: 18/613,001

(22) Filed: Mar. 21, 2024

Related U.S. Application Data
(60) Provisional application No. 63/493,970, filed on Apr. 3, 2023.

(51) Int. Cl. H01L 27/12; H01L 25/16; H01L 25/18; H01L 23/00; H01L 23/498

(52) U.S. Cl. CPC H01L 27/1248; H01L 25/167; H01L 25/18; H01L 27/1259; H01L 23/4985; H01L 24/16; H01L 24/32; H01L 24/73; H01L 27/124; H01L 2224/16145; H01L 2224/32227; H01L 2224/73203; H01L 2924/1426

(57) ABSTRACT

An electronic device may include a substrate, an array of display pixels formed on the substrate, first conductive contacts on the substrate, second conductive contacts on the substrate, a flexible printed circuit that is attached to the first conductive contacts, a display driver integrated circuit that is attached to the second conductive contacts, and conductive traces that electrically connect the first conductive contacts to the second conductive contacts. A dielectric layer may cover at least the sidewalls of the conductive traces to protect the conductive traces from damage by an etchant. Subsequently, some or all of the dielectric layer may be removed to prevent damage caused by moisture ingress into the cladding layer.

This application claims priority to U.S. provisional patent application No. 63/493,970 filed Apr. 3, 2023, which is hereby incorporated by reference herein in its entirety.

### BACKGROUND

This relates generally to electronic devices, and, more particularly, to electronic devices with displays.

Electronic devices often include displays. For example, an electronic device may have an organic light-emitting diode (OLED) display based on organic light-emitting diode pixels or a liquid crystal display (LCD) based on liquid crystal display pixels. The display may include display driver circuitry that is configured to provide display data to the pixels and gate driver circuitry that is configured to control the pixels.

It is within this context that the embodiments herein arise.

### SUMMARY

An electronic device may include a substrate, an array of display pixels formed on the substrate, first conductive contacts on the substrate, second conductive contacts on the substrate, a flexible printed circuit that is attached to the first conductive contacts, a display driver integrated circuit that is attached to the second conductive contacts, conductive traces that electrically connect the first conductive contacts to the second conductive contacts, and a dielectric layer that at least partially covers the conductive traces. At least one trench may be formed in the dielectric layer that separates the dielectric layer into discrete portions separated by gaps.

An electronic device may include a substrate, a conductive trace on the substrate, and an organic dielectric layer that at least partially covers the conductive trace. At least one trench may be formed in the organic dielectric layer that divides the organic dielectric layer into discrete portions separated by at least one gap.

A method may include forming a conductive trace with sidewalls on a substrate, forming, along the length of the conductive trace, a dielectric layer over at least the sidewalls of the conductive trace, exposing the conductive trace and the dielectric layer to an etchant, and after exposing the conductive trace and the dielectric layer to the etchant, removing at least some of the dielectric layer.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3 is a cross-sectional side view of an illustrative electronic device with a display driver integrated circuit that is mounted on a display substrate in accordance with some embodiments.

FIG. 4 is a cross-sectional side view of illustrative method steps for forming conductive traces on a display substrate in accordance with some embodiments.

FIG. 5 is a cross-sectional side view of illustrative method steps for forming conductive traces and a cladding layer on a display substrate in accordance with some embodiments.

FIG. 6 is a top view of an illustrative display with conductive traces in a trace region and a cladding layer that is formed along the entire length of the conductive traces in accordance with some embodiments.

FIG. 7 is a cross-sectional side view of illustrative method steps for forming conductive traces using a cladding layer that is subsequently at least partially removed in accordance with some embodiments.

FIG. 8 is a top view of an illustrative display with conductive traces in a trace region and no cladding layer in the trace region in accordance with some embodiments.

FIG. 9 is a top view of an illustrative display with conductive traces in a trace region and a cladding layer that has trenches in the trace region in accordance with some embodiments.

### DETAILED DESCRIPTION

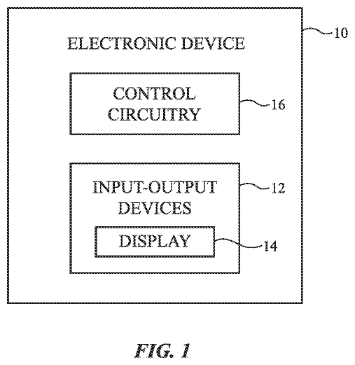

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

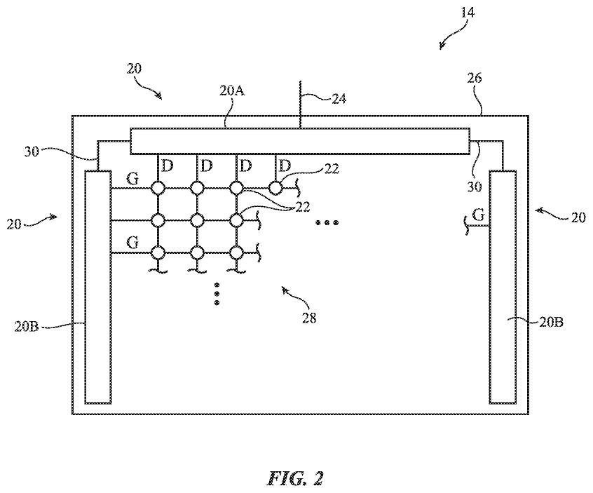

FIG. 2 is a diagram of an illustrative display 14. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels. Pixels of other colors such as cyan, magenta, and yellow might also be used.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally across display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

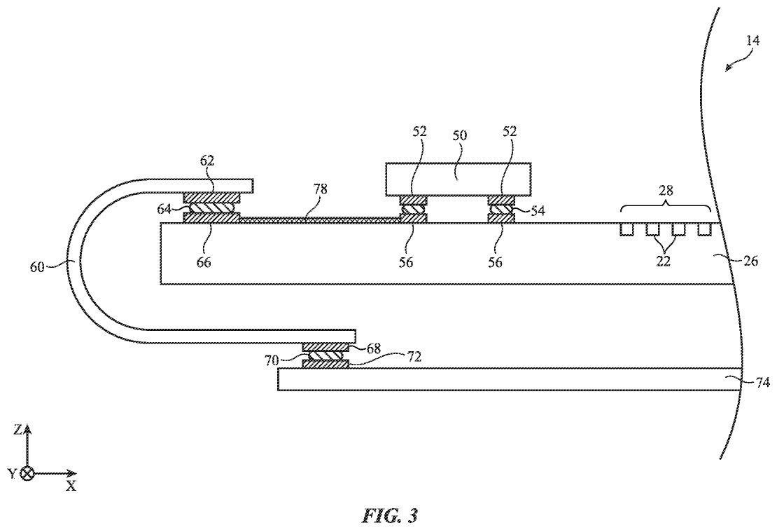

FIG. 3 is a cross-sectional side view of an illustrative display. The display may include a substrate 26 formed from glass, silicon, plastic, or any other desired material. Substrate 26 may include circuitry (transistors) that is used to operate pixels 22. Substrate 26 may sometimes be referred to as a thin-film transistor substrate.

In the example of FIG. 3, a display driver integrated circuit (DDIC) 50 is included in the electronic device. The display driver integrated circuit 50 includes display driver circuitry for the display such as display driver circuitry 20A in FIG. 2. Display driver integrated circuit 50 is configured to provide data and other control signals to display 14 to control operations of pixels 22.

As shown in FIG. 3, display driver integrated circuit 50 may be mounted (attached) directly to substrate 26. Display driver integrated circuit 50 includes contacts 52 (sometimes referred to as contact pads 52) that are configured to electrically connect to contacts 56 (sometimes referred to as contact pads 56 or bond pads 56) in substrate 26. Contacts 52 of display driver integrated circuit 50 may be bonded to contacts 56 of substrate 26 using conductive bonding structures 54 (sometimes referred to as conductive interconnect structures 54, conductive attachment structures 54, etc.). Conductive bonding structures 54 may be, for example, formed from anisotropic conductive films (ACF) and/or solder. A conductive bonding structure 54 is interposed between each respective contact 52 and contact 56. Conductive bonding structures 54 are used to bond DDIC 50 to substrate 26. The conductive bonding structures may form a physical and electrical connection between DDIC 50 and substrate 26.

Display driver integrated circuit 50 may receive signals from flexible printed circuit 60. The flexible printed circuit 60 may be coupled between substrate layer 26 and printed circuit board 74. Flexible printed circuit 60 may be formed from one or more dielectric layers formed from a flexible material such as polyimide. Metal traces may be printed on the one or more dielectric layers. Printed circuit board 74 may be, for example, a rigid printed circuit board (sometimes referred to as a motherboard).

Flexible printed circuit 60 includes one or more contacts 62 (sometimes referred to as contact pads 62) and one or more contacts 68 (sometimes referred to as contact pads 68). Contacts 62 are electrically connected to a respective contact 66 (sometimes referred to as contact pads 66 or bond pads 66) in substrate 26 by conductive bonding structures 64 (sometimes referred to as conductive interconnect structures 64, conductive attachment structures 64, etc.). Contacts 68 are electrically connected to a respective contact 72 (sometimes referred to as contact pads 72 or bond pads 72) in rigid printed circuit board 74 by conductive bonding structures 70 (sometimes referred to as conductive interconnect structures 70, conductive attachment structures 70, etc.). Conductive bonding structures 64 and 70 may be, for example, formed from anisotropic conductive films and/or solder. A conductive bonding structure 64 is interposed between each respective contact 62 and contact 66. The conductive bonding structures 64 may form a physical and electrical connection between flexible printed circuit 60 and substrate 26. A conductive bonding structure 70 is interposed between each respective contact 68 and contact 72. The conductive bonding structures 70 may form a physical and electrical connection between flexible printed circuit 60 and rigid printed circuit board 74.

One or more conductive traces 78 (sometimes referred to herein as traces 78, metal traces 78, connection traces 78, etc.) may be formed on substrate 26 between contacts 66 and contacts 56. In other words, the conductive traces 78 provide one or more paths for signals from flexible printed circuit 60 (at contacts 66) to be provided to display driver integrated circuit 50 (at contacts 56). Each conductive trace 78 may be electrically connected between at least one contact 66 at a first end and at least one contact 56 at a second end.

During operations of the electronic device of FIG. 3, signals for operating the display (e.g., control signals and/or display data) may be provided from control circuitry within rigid printed circuit board 74 to flexible printed circuit 60. The flexible printed circuit 60 conveys the signals to substrate 26 (e.g., to contact pads 66). Thereafter, display driver integrated circuit 50 receives the signals from traces 78 on substrate 26 (e.g., using a subset of contact pads 56). Display driver integrated circuit 50 may output corresponding signals for operating the display to substrate 26 (e.g., using a different subset of contact pads 56). The signals from display driver integrated circuit 50 may subsequently be used by circuitry within substrate 26 to operate the display.

If care is not taken, traces 78 between contacts 66 (that are electrically connected to the flexible printed circuit) and contacts 56 (that are electrically connected to the display driver integrated circuit) may not be as robust as desired.

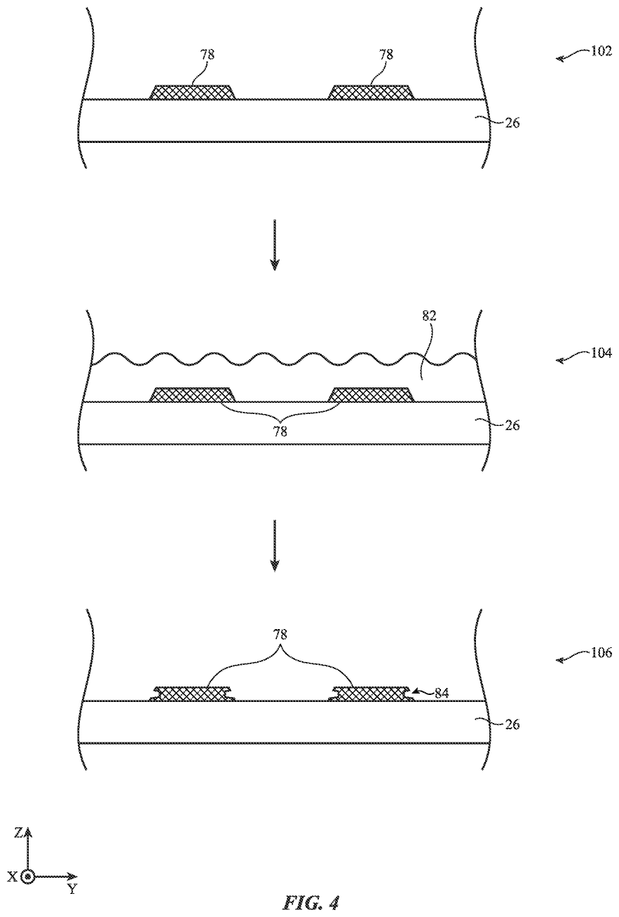

A method for forming traces 78 is shown in FIG. 4. First, at step 102, traces 78 may be formed on substrate 26 (e.g., using any desired deposition and/or patterning steps). During the manufacturing process for display 14, traces 78 may be exposed to an etchant 82 at step 104. Etchant 82 may be used to pattern anode electrodes for display pixels 22 in pixel array 28, as one example. Etchant 82 is not intended to impact traces 78 but traces 78 may be exposed to etchant 82 due to manufacturing preferences and/or limitations. If care is not taken, exposure of traces 78 to etchant 82 may have adverse effects on the reliability of display 14.

As shown at step 106, exposure of traces 78 (and particularly the sidewalls of traces 78) to etchant 82 may cause damage such as undercuts (voids) in the sidewalls of traces 78. This damage to traces 78 may reduce the reliability of traces 78 during subsequent operations of display 14.

Moreover, exposure of traces 78 (and particularly the sidewalls of traces 78) to etchant 82 may cause undesirable particle generation. For example, particles originating from traces 78 such as silver particles may cause visible artifacts (e.g., perceptible black dots) during subsequent operations of display 14.

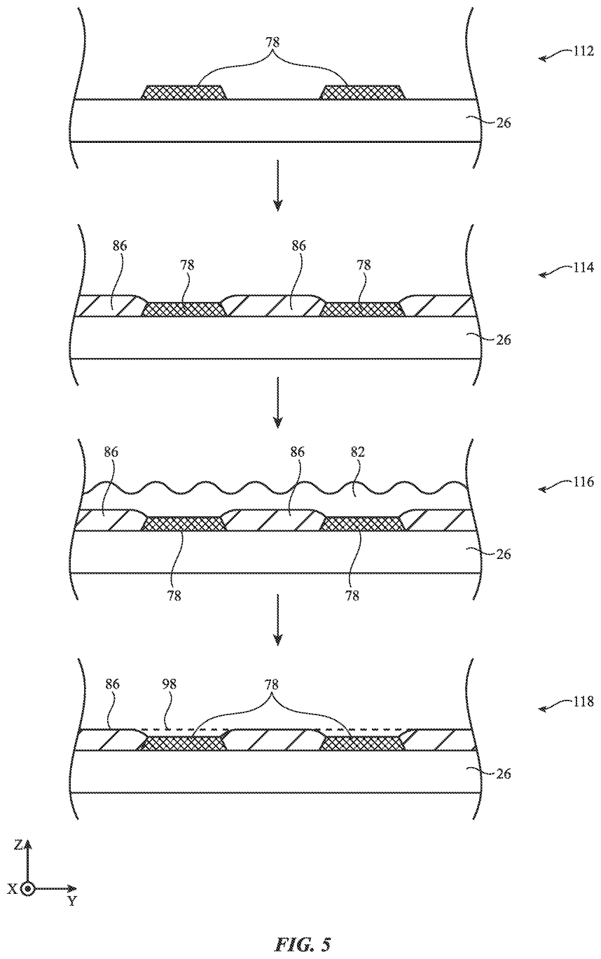

To mitigate the aforementioned issues associated with exposure of traces 78 (and particularly the sidewalls of traces 78) to etchant 82, a protective dielectric layer may cover at least the sidewalls of traces 78 when the traces are exposed to the etchant. A method of this type is shown in FIG. 5.

First, at step 112, traces 78 may be formed on substrate 26 (e.g., using any desired deposition and/or patterning steps). Next, at step 114, a protective dielectric layer 86 (sometimes referred to as cladding 86, cladding layer 86, protective layer 86, dielectric layer 86, planarization layer 86, organic layer 86, organic dielectric layer 86, organic planarization layer 86, etc.) is formed between traces 78. As shown in FIG. 5, dielectric layer 86 covers at least the sidewalls of traces 78. Dielectric layer 86 may be formed from an organic dielectric material or any other desired material.

After cladding 86 is covering the sidewalls of traces 78, the etching step is performed at step 116 (similar to as in step 104 of FIG. 4). As shown, traces 78 and cladding layer 86 are exposed to etchant 82 while etchant 82 is used to pattern anode electrodes for display pixels 22 in pixel array 28. However, the cladding layer 86 protects the sidewalls of traces 78 from damage during the etching step. Consequently, after etching is complete and etchant 82 is no longer present (as shown in step 118), traces 78 do not have sidewall damage/voids.

Including cladding 86 to cover the sidewalls of traces 78 therefore mitigates reliability issues associated with exposure of traces 78 (and particularly the sidewalls of traces 78) to etchant 82.

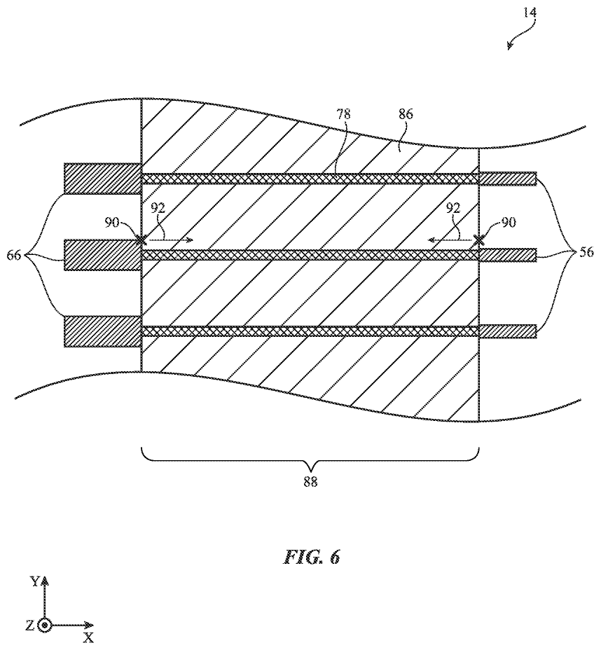

FIG. 6 is a top view of an illustrative display 14 with a region 88 (sometimes referred to as trace region 88, trace area 88, transition area 88, etc.) that includes traces 78 between contacts 66 (that are electrically connected to the flexible printed circuit) and contacts 56 (that are electrically connected to the display driver integrated circuit). As shown in FIG. 6, cladding layer 86 is included across the entire region 88 between contacts 66 and contacts 56. In other words, cladding layer 86 is present along the entire length of each trace 78.

Although cladding layer 86 desirably mitigates damage to traces 78 during manufacturing, the cladding layer may undesirably provide a moisture ingress path that can cause damage to traces 78. As shown in FIG. 6, the display may be susceptible to damage and/or cracking near contacts 56 and 66 (e.g., at points 90). For example, cladding layer 86 may crack adjacent to contacts 66 during bonding of contacts 66 to contacts 62 on flexible printed circuit 60 and/or cladding layer 86 may crack adjacent to contacts 56 during bonding of contacts 56 to contacts 52 on display driver integrated circuit 50. A crack in the cladding layer serves as a point of ingress into cladding layer 86 (e.g., at either point 90 in FIG. 6). Moisture may then penetrate through cladding layer 86 towards the middle of region 88 as shown by arrows 92. This type of moisture penetration in region 88 may cause reliability issues such as the electrical connection between contacts 66 and 56 using traces 78 being broken.

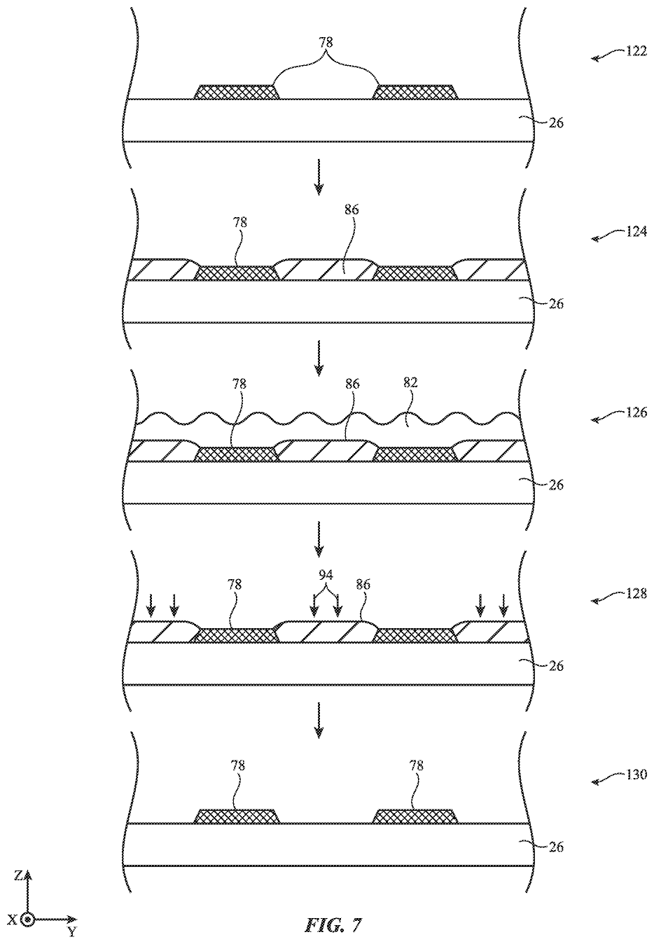

To mitigate reliability issues associated with moisture ingress into cladding layer 86, some or all of cladding layer 86 may be removed in trace region 88 after the cladding layer 86 has been used to protect traces 78 from damage during etching. FIG. 7 is a cross-sectional side view showing a method of this type. First, at step 122, traces 78 may be formed on substrate 26 (e.g., using any desired deposition and/or patterning steps). Next, at step 124, protective dielectric layer 86 is formed between traces 78 similar to as discussed in connection with step 114 of FIG. 5.

After cladding 86 is covering the sidewalls of traces 78, the etching step is performed at step 126 (similar to as in step 116 of FIG. 4). Traces 78 and cladding layer 86 are exposed to etchant 82 while etchant 82 is used to pattern anode electrodes for display pixels 22 in pixel array 28. The cladding layer 86 protects the sidewalls of traces 78 from damage during the etching step.

At step 128, some or all of cladding layer 86 may be removed (once the etching of step 126 is complete and etchant 82 is no longer present). As shown in FIG. 7, ashing (sometimes referred to as plasma ashing) is performed by applying an etchant material on the cladding as shown by arrows 94. The ashing process in step 128 may use any desired plasma material including any desired gas (e.g., oxygen, argon) or liquid.

After the plasma ashing is complete, as shown at step 130, traces 78 are present on substrate 26 and do not have sidewall damage/voids. Moreover, the cladding layer 86 is no longer present, preventing moisture ingress in the trace region through the cladding layer.

Removing cladding 86 after the cladding has protected the traces 78 during etching therefore mitigates both the reliability issues associated with exposure of traces 78 to etchant 82 and the reliability issues associated with moisture ingress through cladding 86.

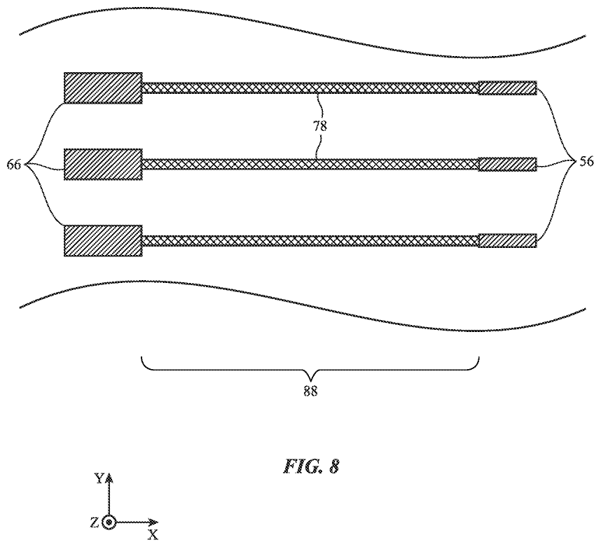

FIG. 8 is a top view of an illustrative display 14 with a region 88 (sometimes referred to as trace region 88, trace area 88, transition area 88, etc.) that does not include any of cladding layer 86. In other words, cladding layer 86 is removed from all of region 88 at step 128 in FIG. 7 to produce the trace region 88 shown in FIG. 8. In this example, there may be no organic dielectric material between any of the adjacent traces 78 in region 88. There may be no organic dielectric material along the entire length of each trace 78.

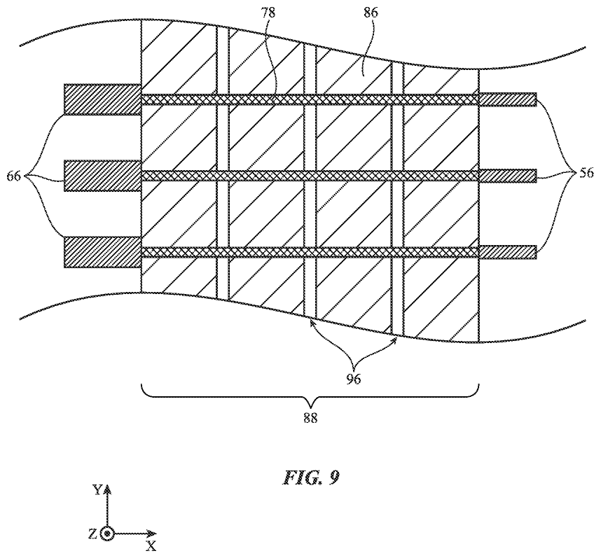

In another example, shown in FIG. 9, cladding layer 86 may be removed in some but not all of region 88. Specifically, cladding layer 86 may only be removed in one or more strips across region 88. In FIG. 9, cladding layer 86 is still formed in some of region 88 with traces 78. At least some organic dielectric material is formed between each pair of adjacent traces 78 in region 88.

As shown in FIG. 9, one or more trenches 96 are included in cladding layer 86 in region 88. Each trench 96 may refer to a region in which layer 86 has been removed (e.g., at step 128 in FIG. 7). The presence of trench 96 causes a gap between different portions of cladding layer 86. Each gap may have any desired width (e.g., more than 1 micron, more than 10 microns, more than 100 micron, more than 1,000 microns, less than 1 micron, less than 10 microns, less than 100 micron, less than 1,000 microns, etc.). The gap between portions of cladding layer 86 effectively cuts off the moisture ingress path through cladding layer 86. In other words, moisture may only penetrate as far as trench 96.

In FIG. 9, three trenches 96 are included in cladding layer 86 in FIG. 9. This example is merely illustrative. If desired, only two trenches may be included in cladding layer 86, only one trench may be included in cladding layer 86, or more than three trenches may be included in cladding layer 86.

Each trench 96 may be interposed between contacts 66 and contacts 56 such that contacts 56 are formed on a first side of the trench and contacts 66 are formed on a second, opposing side of the trench.

Each trace 78 may extend in a first direction between contacts 66 and contacts 56. Each trench may extend in a second direction that is non-parallel to the first direction. The second direction may be orthogonal to the first direction (as in FIG. 9) or at a non-orthogonal, non-parallel angle relative to the first direction.

In FIGS. 5-9, cladding layer 86 is depicted as covering the sidewalls of traces 78 without completely covering the tops of traces 78. This example is merely illustrative. If desired, cladding layer 86 may completely cover both the sidewalls and tops (upper surfaces) of traces 78 (e.g., as indicated by dashed line 98 at step 118 in FIG. 5).

In connection with FIGS. 7-9, an example is described where cladding layer 86 is used for protection of traces that provide signals from a flexible printed circuit to a display driver integrated circuit (and then subsequently at least partially removed). This example is merely illustrative. In general, the techniques of FIG. 7 may be applied to any desired portion of display 14 and/or electronic device 10. These techniques may be used on conductive traces or other conductive components adjacent to a physical hole in the display, as one additional example. In general, any desired conductive trace or component may be protected by a cladding layer that is subsequently removed as in FIG. 7.

The foregoing is merely illustrative and various modifications can be made by those skilled in the art without departing from the scope and spirit of the described embodiments. The foregoing embodiments may be implemented individually or in any combination.

What is claimed is:

1. An electronic device comprising:
a substrate;
an array of display pixels formed on the substrate;
first conductive contacts on the substrate;
second conductive contacts on the substrate;
a flexible printed circuit that is attached to the first conductive contacts;
a display driver integrated circuit that is attached to the second conductive contacts;
conductive traces that electrically connect the first conductive contacts to the second conductive contacts; and
a dielectric layer that at least partially covers the conductive traces, wherein at least one trench is formed in the dielectric layer that separates the dielectric layer into discrete portions separated by gaps.

2. The electronic device defined in claim 1, further comprising:
a rigid printed circuit board, wherein the flexible printed circuit board is attached between the first conductive contacts on the substrate and the rigid printed circuit board.

3. The electronic device defined in claim 1, wherein the dielectric layer comprises an organic dielectric material.

4. The electronic device defined in claim 1, wherein the dielectric layer covers sidewalls of the conductive traces but does not completely cover tops of the conductive traces.

5. The electronic device defined in claim 1, wherein the dielectric layer completely covers both sidewalls and tops of the conductive traces.

6. The electronic device defined in claim 1, wherein a first trace extends in a first direction between the first conductive contacts and the second conductive contacts and wherein a first trench of the at least one trench extends in a second direction that is non-parallel to the first direction.

7. The electronic device defined in claim 1, wherein the at least one trench comprises two trenches.

8. An electronic device comprising:
a substrate;
a conductive trace on the substrate; and
an organic dielectric layer that at least partially covers the conductive trace, wherein at least one trench is formed in the organic dielectric layer that divides the organic dielectric layer into discrete portions separated by at least one gap.

9. The electronic device defined in claim 8, wherein the conductive trace has sidewalls and an upper surface and wherein, in portions of the conductive trace not aligned with the at least one trench, the organic dielectric layer overlaps the sidewalls.

10. The electronic device defined in claim 9, wherein, in portions of the conductive trace aligned with the at least one trench, the organic dielectric layer does not overlap the sidewalls or upper surface.

11. The electronic device defined in claim 8, wherein the conductive trace has sidewalls and an upper surface and wherein, in portions of the conductive trace not aligned with the at least one trench, the organic dielectric layer overlaps the sidewalls and the upper surface.

12. The electronic device defined in claim 11, wherein, in portions of the conductive trace aligned with the at least one trench, the organic dielectric layer does not overlap the sidewalls or upper surface.

13. The electronic device defined in claim 8, wherein the at least one trench comprises two or more trenches that are non-parallel to the conductive trace.

14. A method comprising:
forming a conductive trace on a substrate, wherein the conductive trace has sidewalls;
forming, along the length of the conductive trace, a dielectric layer over at least the sidewalls of the conductive trace;
exposing the conductive trace and the dielectric layer to an etchant; and
after exposing the conductive trace and the dielectric layer to the etchant, removing at least some of the dielectric layer.

15. The method defined in claim 14, wherein the conductive trace has an upper surface and wherein forming the dielectric layer over at least the sidewalls of the conductive trace comprises forming the dielectric layer over the sidewalls of the conductive trace without completely covering the upper surface of the conductive trace.

16. The method defined in claim 14, wherein removing at least some of the dielectric layer comprises removing the dielectric layer along the length of the conductive trace.

17. The method defined in claim 14, wherein removing at least some of the dielectric layer comprises removing the dielectric layer along some but not all of the length of the conductive trace.

18. The method defined in claim 14, wherein removing at least some of the dielectric layer comprises removing the dielectric layer along one or more strips that are non-parallel to the conductive trace.

19. The method defined in claim 14, wherein removing at least some of the dielectric layer comprises performing plasma ashing.

20. The method defined in claim 14, wherein exposing the conductive trace and the dielectric layer to the etchant comprises exposing the conductive trace and the dielectric layer to the etchant while the etchant is used to pattern anodes for display pixels in a pixel array.
